(19) United States
(12) Patent Application Publication
(10) Pub. No.: US 2025/0317145 A1
(43) Pub. Date: Oct. 9, 2025

(54) BUFFER CIRCUIT HAVING ENHANCED SLEW RATE

(71) Applicant: MagnaChip Semiconductor, Ltd., Cheongju-si (KR)

(72) Inventor: Sangho LEE, Cheongju-si (KR)

(73) Assignee: MagnaChip Semiconductor, Ltd., Cheongju-si (KR)

(21) Appl. No.: 18/904,388

(22) Filed: Oct. 2, 2024

(30) Foreign Application Priority Data
Apr. 9, 2024 (KR) 10-2024-0048022

(51) Int. Cl. H03K 19/003; H03K 17/16

(52) U.S. Cl. CPC H03K 19/00361; H03K 17/161

(57) ABSTRACT

A buffer circuit configured to generate an output voltage according to an input voltage includes: an input stage configured to provide first and second differential currents to a load stage or receive third and fourth differential currents from the load stage based on a difference between the input voltage and the output voltage; a load stage configured to apply gate voltages to first and second output transistors of an output stage based on the first through fourth differential currents; the output stage configured to regulate the output voltage based on the gate voltages applied to the first and the second output transistors; and a slew rate compensator configured to regulate the gate voltages of the first and second output transistors by providing a source current to the load stage or receiving a sink current from the load stage.

### CROSS REFERENCE TO RELATED APPLICATION

The present application claims the benefit under 35 USC § 119 (a) of Korea Patent Application No. 10-2024-0048022, filed on Apr. 9, 2024, the entire disclosure of which is incorporated herein by reference for all purposes.

### BACKGROUND

### 1. Field

The following description relates to a circuit configured to improve a slew rate of a buffer circuit, and more particularly, to a slew rate compensator including a source follower.

### 2. Discussion of Related Art

The statements in this section merely provide background information related to the present disclosure and do not necessarily constitute prior art.

Display driver integrated circuits (DDIC) are widely used in devices such as portable electronic devices (e.g., smartphones, tablet personal computers) and vehicle displays (digital instrument clusters, navigation, etc.). DDIC is a source driving circuit for driving display panels such as LCD and OLED devices and includes an output buffer circuit that outputs data. For these DDICs, there is a growing need for performance improvements related to high resolution, display quality, low power consumption, and more.

A buffer circuit of the DDIC's source driving circuit exists independently for each R/G/B representing a pixel, or exists only for each R/G/B pixel, but may be time divided to drive each R/G/B pixel. During the time-division driving, the time given to each source driving circuit for data output is reduced, and the slew rate of the buffer circuit must be improved accordingly. In addition, a large number of source driving circuits and buffer circuits are required to satisfy high resolution, which greatly affects the size and power consumption of the entire DDIC.

Therefore, there is a need for a buffer circuit that can improve the slew rate, alleviate size constraints, and be implemented at low power.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a buffer circuit configured to generate an output voltage according to an input voltage includes: an input stage configured to provide first and second differential currents to a load stage or receive third and fourth differential currents from the load stage based on a difference between the input voltage and the output voltage; a load stage configured to apply gate voltages to first and second output transistors of an output stage based on the first through fourth differential currents; the output stage configured to regulate the output voltage based on the gate voltages applied to the first and the second output transistors; and a slew rate compensator configured to regulate the gate voltages of the first and second output transistors by providing a source current to the load stage or receiving a sink current from the load stage. The slew rate compensator includes: a source follower configured to output a corrected input voltage obtained by reducing the input voltage by a threshold voltage of a MOS transistor; and a first control circuit configured to control a magnitude of the corrected input voltage output from the source follower.

The first control circuit may include a first control NMOS transistor having a drain connected to the source follower; a source connected to a ground voltage; and a gate to which a gate voltage of the second output transistor is applied.

The slew rate compensator may further include: a first comparator configured to enter an ON operating state or an OFF operating state based on the difference between the input voltage and the output voltage; a second comparator configured to enter an ON operating state or an OFF operating state based on a difference between the corrected input voltage and the output voltage; a source current circuit configured to provide the source current to the load stage; a sink current circuit configured to receive the sink current from the load stage; a slew rate compensation switch configured to determine whether the source current circuit or the sink current circuit is operating; and a second control circuit configured to control the corrected input voltage output from the source follower.

The second control circuit may include: a first control PMOS transistor configured to operate as a current source; and a second control PMOS transistor having a drain connected to the first control PMOS transistor; a source connected to a power supply voltage; and a gate to which a gate voltage of the first output transistor is applied. The first comparator may include: an NMOS transistor having a gate connected to the input voltage; a drain connected to the source current circuit; and a source connected to the output voltage, and the second comparator may include: a PMOS transistor having a gate connected to the corrected input voltage output from the source follower; a drain connected to the sink current circuit; and a source connected to the output voltage, and the NMOS transistor may have a body connected in common with the source and configured to receive the output voltage.

The source follower may include: a first source follower NMOS transistor having a gate connected to the input voltage, a drain connected to a power supply voltage, a source connected to the gate of the PMOS transistor of the second comparator, and a body connected in common with the source, and the source follower may provide the corrected input voltage to the gate of the PMOS transistor of the second comparator.

The source current circuit may include: a first source PMOS transistor having a gate connected to the first comparator; a drain connected in common with the gate; and a source connected to a power supply voltage, and configured to allow a source reference current to flow therethrough; and a second source PMOS transistor having a gate connected in common with the first source PMOS transistor; a drain connected to a fourth node of the load stage having a mirroring structure with and corresponding to a third node of the load stage connected to a gate terminal of the second output transistor; and a source connected to the power supply voltage, and configured to allow the source current to flow therethrough by mirroring the source reference current.

The sink current circuit may include: a first sink NMOS transistor having a gate connected to the second comparator; a drain connected in common with the gate; and a source connected to a ground voltage, and configured to allow a sink reference current to flow therethrough; and a second sink NMOS transistor having a gate connected in common with the gate of the first sink NMOS transistor; a drain connected to a second node of the load stage having a mirroring structure with and corresponding to a first node of the load stage connected to a gate terminal of the first output transistor; and a source connected to the ground voltage, and configured to allow the sink current to flow therethrough by mirroring the sink reference current.

The load stage may include: a first differential mirror circuit having a current mirroring structure and a cascode structure, and configured to mirror the first and second differential currents and the sink current; a second differential mirror circuit having a current mirroring structure and a cascode structure, and configured to mirror the third and fourth differential currents and the source current; and a third bias circuit and a fourth bias circuit connected between the first differential mirror circuit and the second differential mirror circuit, and configured to control an operation in a static state and an amplification operation of the first differential mirror circuit and the second differential mirror circuit.

In another general aspect, a buffer circuit configured to generate an output voltage according to an input voltage includes: an input stage configured to provide first and second differential currents to a load stage or receive third and fourth differential currents from the load stage based on a difference between the input voltage and the output voltage; a load stage configured to apply gate voltages to first and second output transistors of an output stage based on the first through fourth differential currents; the output stage configured to regulate the output voltage based on the gate voltages applied to the first and the second output transistors; and a slew rate compensator configured to regulate the gate voltages of the first and the second output transistors by providing a source current to the load stage or receiving a sink current from the load stage. The slew rate compensator includes: a source follower configured to output a corrected input voltage obtained by reducing the input voltage by a threshold voltage of a MOS transistor; and a second control circuit configured to control the corrected input voltage output from the source follower.

The second control circuit may include: a first control PMOS transistor configured to operate as a current source, and a second control PMOS transistor having a drain connected to the first control PMOS transistor; a source connected to a power supply voltage; and a gate to which a gate voltage of the first output transistor is applied.

The slew rate compensator may further include: a first comparator configured to enter an ON operating state or an OFF operating state based on the difference between the input voltage and the output voltage; a second comparator configured to enter an ON operating state or an OFF operating state based on a difference between the corrected input voltage and the output voltage; a source current circuit configured to provide the source current to the load stage; a sink current circuit configured to receive the sink current from the load stage; a slew rate compensation switch configured to determine whether the source current circuit or the sink current circuit is operating; and a first control circuit configured to control a magnitude of a current of the source follower. The source follower includes a first source follower NMOS transistor having a gate connected to the input voltage; a drain connected to a power supply voltage; a source connected to a gate of a PMOS transistor of the second comparator; and a body connected in common with the source. The source follower is configured to provide the corrected input voltage to the gate of the PMOS transistor of the second comparator.

The first control circuit may include: a first control NMOS transistor having a drain connected to the source follower; a source connected to a ground voltage; and a gate to which a gate voltage of the second output transistor is applied.

The first comparator may include: an NMOS transistor having a gate connected to the input voltage; a drain connected to the source current circuit; and a source connected to the output voltage. The second comparator may include: a PMOS transistor having a gate connected to the corrected input voltage output from the source follower; a drain connected to the sink current circuit; and a source connected to the output voltage. The NMOS transistor may have a body connected in common with the source and configured to receive the output voltage.

The source current circuit may include: a first source PMOS transistor having a gate connected to the first comparator; a drain connected in common with the gate; and a source connected to a power supply voltage, and configured to allow a source reference current to flow therethrough; and a second source PMOS transistor having a gate connected in common with the gate of the first source PMOS transistor; a drain connected to fourth node of the load stage having a mirroring structure with and corresponding to a third node of the load stage connected to a gate terminal of the second output transistor; and a source connected to the power supply voltage, and configured to allow the source current to flow therethrough by mirroring the source reference current.

The sink current circuit may include: a first sink NMOS transistor having a gate connected to the second comparator; a drain connected in common with the gate; and a source connected to a ground voltage, and configured to allow a sink reference current to flow therethrough; and a second sink NMOS transistor having a gate connected in common with the gate of the first sink NMOS transistor; a drain connected to a second node of the load stage having a mirroring structure with and corresponding to a first node of the load stage connected to a gate terminal of the first output transistor; and a source connected to the ground voltage, and configured to allow the sink current to flow therethrough by mirroring the sink reference current.

The load stage may include: a first differential mirror circuit having a current mirroring structure and a cascode structure, and configured to mirror the first and second differential currents and the sink current; a second differential mirror circuit having a current mirroring structure and a cascode structure, and configured to mirror the third and fourth differential currents and the source current; and a third bias circuit and a fourth bias circuit connected between the first differential mirror circuit and the second differential mirror circuit, and configured to control an operation in a static state and an amplification operation of the first differential mirror circuit and the second differential mirror circuit.

In another general aspect, a method for controlling a buffer circuit includes: comparing an input voltage to an output voltage of a buffer circuit; allowing a slew rate compensator to provide a source current to a load stage or receive a sink current from the load stage based on a difference between the input voltage and the output voltage; allowing first and second compensation currents to flow through first and second differential mirror circuits of the load stage based on the source current and the sink current; allowing gate voltages of first and second output transistors of an output stage to increase or decrease based on the first and second compensation currents; and allowing the output voltage to follow a rising transition or a falling transition of the input voltage based on the increase or the decrease in the gate voltages of the first and second output transistors. The allowing of the output voltage to follow the rising transition or the falling transition of the input voltage further includes: allowing a first control circuit to be turned on or turned off.

The method may further include: when the input voltage is in a rising transition, comparing the input voltage to the output voltage, wherein when the input voltage exceeds a value obtained by adding a threshold voltage of a MOS transistor to the output voltage, allowing the slew rate compensator to provide the source current to the load stage; allowing the second compensation current to flow through the second differential mirror circuit based on the source current; allowing the gate voltages of the first and second output transistors of the output stage to decrease based on the second compensation current; allowing the output voltage to increase in response to the decrease in the gate voltages of the first and second output transistors and to follow the rising transition of the input voltage; and allowing the first control circuit to be turned off and the second control circuit to be turned on according to the rising transition of the input voltage.

The method may further include: when the input voltage is in a falling transition, providing the input voltage to a source follower and outputting a corrected input voltage obtained by reducing the input voltage by a threshold voltage of a transistor inside the source follower; comparing the corrected input voltage to the output voltage, wherein when the corrected input voltage is less than a value obtained by subtracting a threshold voltage of a MOS transistor from the output voltage, allowing the slew rate compensator to receive the sink current from the load stage; allowing the first compensation current to flow through the first differential mirror circuit based on the sink current; allowing the gate voltages of the first and second output transistors of the output stage to increase based on the first compensation current; allowing the output voltage to decrease in response to the increase in the gate voltages of the first and second output transistors and to follow the falling transition of the input voltage; and allowing the first control circuit to be turned on and the second control circuit connected to the source follower to be turned off according to the falling transition of the input voltage.

According to various embodiments of the present disclosure, it is possible to provide a circuit that improves the slew rate of the buffer circuit which is the source driving device, alleviates size constraints, and can be implemented at low power.

In addition, according to various embodiments of the present disclosure, it is possible to reduce unnecessary power consumption by controlling a magnitude of a current flowing through the source follower according to a change in a slew rate of the buffer circuit.

Other features and aspects will be apparent from the following detailed description, the drawings, and the claims.

### BRIEF DESCRIPTION OF THE DRAWINGS

FIG. 1 is a block diagram illustrating a buffer circuit according to an embodiment of the present disclosure.

FIG. 2 is a diagram illustrating an input stage and a bias circuit according to an embodiment of the present disclosure.

FIG. 3 is a diagram illustrating an input stage and a bias circuit according to another embodiment of the present disclosure.

FIG. 4 is a circuit diagram illustrating a circuit of a load stage and an output stage according to an embodiment of the present disclosure.

FIG. 5 is a circuit diagram illustrating a circuit of a load stage and an output stage according to another embodiment of the present disclosure.

FIG. 6 is a circuit diagram illustrating a circuit of a slew rate compensator according to an embodiment of the present disclosure.

FIG. 7 is a timing diagram of a slew rate compensator according to an embodiment of the present disclosure.

FIG. 8 is a flowchart illustrating a method for improving a slew rate of an output voltage with respect to a rising transition of an input voltage according to an embodiment of the present disclosure.

FIG. 9 is a flowchart illustrating a method for improving a slew rate of an output voltage with respect to a falling transition of an input voltage according to an embodiment of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

Hereinafter, a detailed description will be given as to the embodiments of the present invention with reference to the accompanying drawings in order for those skilled in the art to embody the present invention with ease. But the present invention is susceptible to variations and modifications and not limited to the embodiments described herein.

It is an object of various embodiments of the present disclosure to provide a buffer circuit that can be implemented with improved slew rates, relaxed size constraints, and low power, taking into account the problems described above.

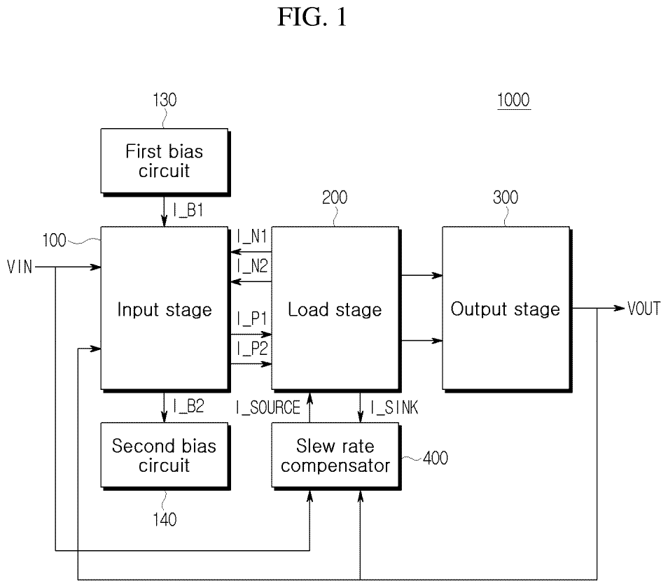

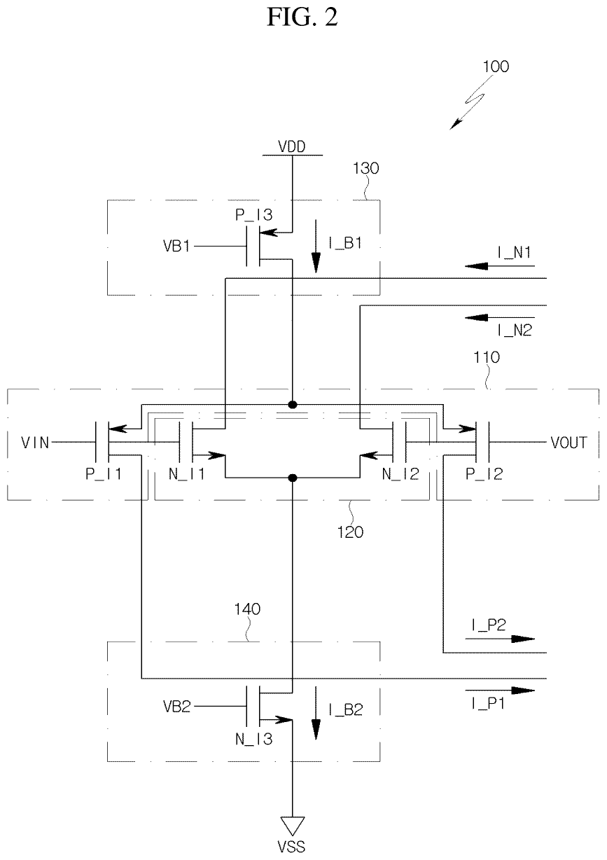

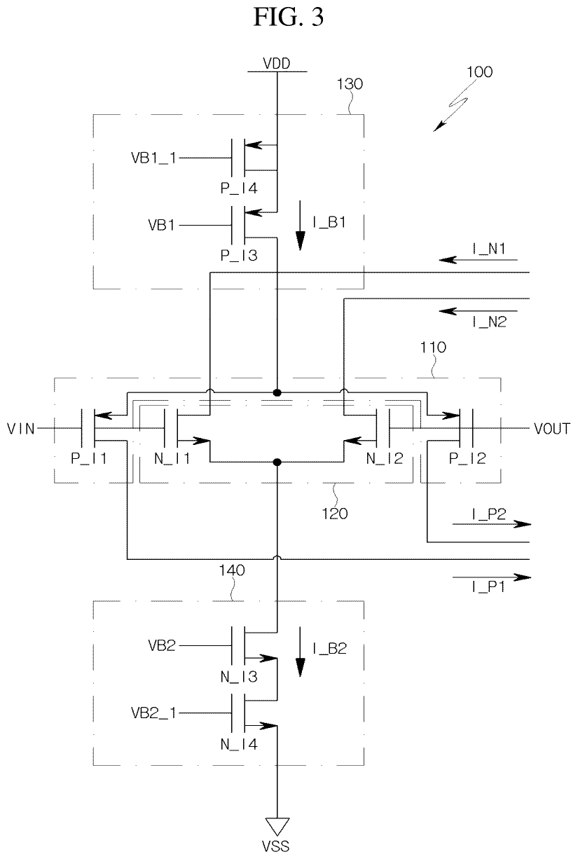

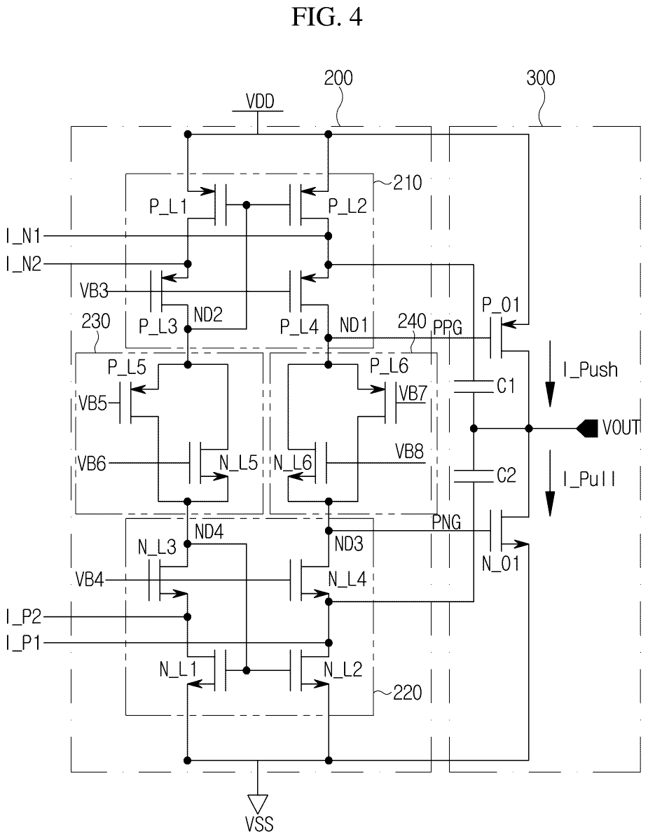

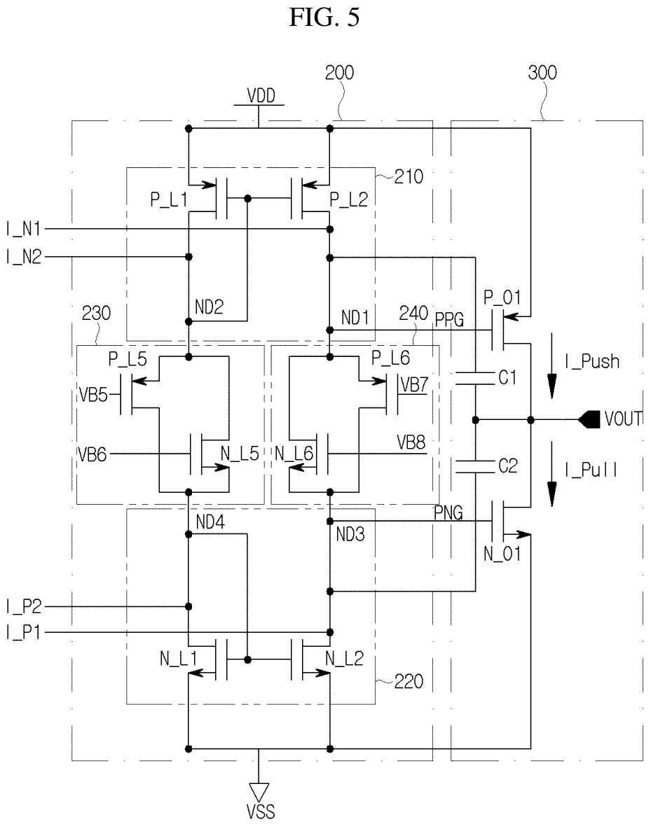

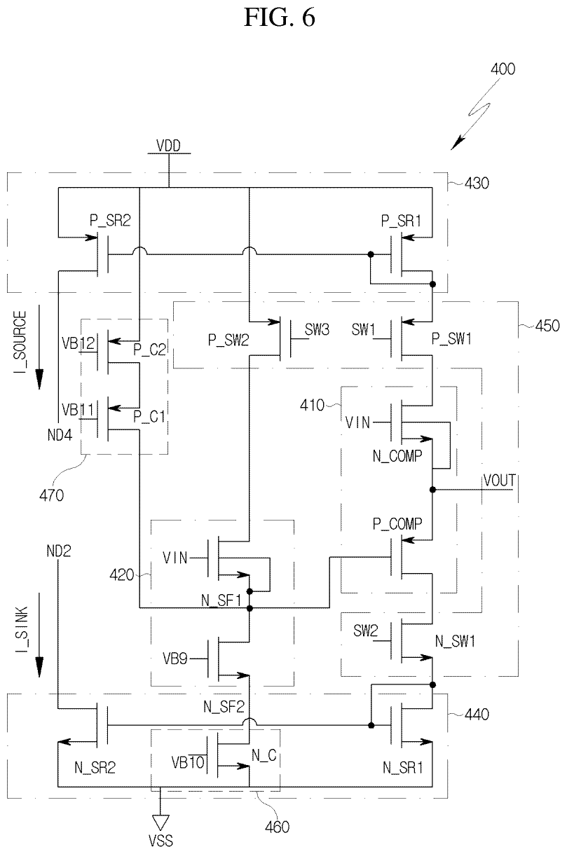

FIG. 1 is a block diagram showing a buffer circuit according to an embodiment of the present disclosure. In the following embodiments, detailed structures of components shown in FIG. 1 will be described with reference to FIGS. 2 to 6. FIG. 2 is a diagram illustrating an input stage and a bias circuit according to an embodiment of the present disclosure, FIG. 3 is a diagram illustrating an input stage and a bias circuit according to another embodiment of the present disclosure, FIG. 4 is a circuit diagram illustrating a circuit of a load stage and an output stage according to an embodiment of the present disclosure, FIG. 5 is a circuit diagram illustrating a circuit of a load stage and an output stage according to another embodiment of the present disclosure, and FIG. 6 is a circuit diagram illustrating a circuit of a slew rate compensator according to an embodiment of the present disclosure.

Referring to FIG. 1, a buffer circuit 1000 according to an example of the present disclosure includes an input stage 100, a load stage 200, an output stage 300, and a slew rate compensator 400. The buffer circuit 1000 amplifies an input voltage VIN to output an output voltage VOUT. When the input voltage VIN increases or decreases, the buffer circuit 1000 may increase or decrease by outputting the output voltage VOUT in response to the increase or decrease. The buffer circuit 1000 may perform feedback on the output voltage VOUT to compare the output voltage VOUT to the input voltage VIN, and may adjust the output voltage VOUT based on a difference in the output voltage VOUT. The buffer circuit 1000 may improve the slew rate, allowing the output voltage VOUT to quickly follow the input voltage VIN in response to a rising transition of the input voltage VIN. Further, the buffer circuit 1000 may improve the slew rate so that the output voltage VOUT can quickly follow the input voltage VIN for a falling transition of the input voltage VIN.

The input stage 100 may provide first and second differential currents I_P1 and I_P2 to the load stage 200 based on a difference between the input voltage VIN and the output voltage VOUT output by the output stage 300 and fed back. Further, the input stage 100 may receive third and fourth differential currents I_N1 and I_N2 from the load stage 200 according to a difference between the input voltage VIN and the output voltage VOUT output from the output stage 300 and fed back. Here, the sum of the first and second differential currents I_P1 and I_P2 and the sum of the third and fourth differential currents I_N1 and I_N2 may be equal to each other. For example, when the input voltage VIN is higher than the output voltage VOUT, the second differential current I_P2 and the third differential current I_N1 increase, and the first differential current I_P1 and the fourth differential current I_N2 decrease, such that the sum of the first and second differential currents I_P1 and I_P2 and the sum of the third and fourth differential currents I_N1 and I_N2 may be equal to each other.

The input stage 100 may have a rail-to-rail structure including double input stages. The input stage 100 may be connected between a power supply voltage VDD and a ground voltage VSS.

The input stage 100 may be connected to a first bias circuit 130. The input stage 100 may receive a first bias current I_B1 from the first bias circuit 130 to operate an internal PMOS transistor. Here, the first bias current I_B1 may act as a constant current source to ensure that the sum of the first and second differential currents I_P1 and I_P2 flowing through the internal PMOS transistor of the input stage 100 is constant.

The input stage 100 may be connected to the second bias circuit 140. The input stage 100 may provide a second bias current I_B2 to the second bias circuit 140 so that the internal NMOS transistor operates. Here, the second bias current may act as a constant current source to ensure that the sum of the third and fourth differential currents I_N1 and I_N2 flowing through the internal NMOS transistor of the input stage 100 is constant.

The first bias circuit 130 may be disposed between a power supply voltage VDD and the input stage 100. The first bias circuit 130 may be connected to the power supply voltage VDD and the input stage 100. The first bias circuit 130 may provide the first bias current I_B1 to the input stage 100 as a constant current source.

The second bias circuit 140 may be disposed between the ground voltage VSS and the input stage 100. The second bias circuit 140 may be connected to the ground voltage VSS and the input stage 100. The second bias circuit 140 may receive the second bias current I_B2 from the input stage 100 as a constant current source.

The load stage 200 may receive the first and second differential currents I_P1 and I_P2 from the input stage 100. The load stage 200 may provide the third and fourth differential currents I_N1 and I_N2 to the input stage 100. The load stage 200 may receive the first and second differential currents I_P1 and I_P2 from the input stage 100 based on the difference between the input voltage VIN and the output voltage VOUT. The load stage 200 may provide the third and fourth differential currents I_N1 and I_N2 to the input stage 100 based on the difference between the input voltage VIN and the output voltage VOUT.

The load stage 200 may increase or decrease the gate voltages of the output transistors of the output stage 300 based on the first through fourth differential currents I_P1, I_P2, I_N1, and I_N2. The load stage 200 may perform a current mirroring operation based on the first through fourth differential currents I_P1, I_P2, I_N1, and I_N2, and may cause current to flow to or from nodes connected to gate terminals of the output transistors of the output stage 300, or let the current flow out of the nodes. When the current flows to the nodes connected to the gate terminals of the output transistors of the output stage 300, the gate voltages of the output transistors may increase. On the other hand, when the current flows out of the nodes connected to the gate terminals of the output transistors, the gate voltages of the output transistors may decrease. When the gate voltages of the output transistors increase, the output voltage VOUT decreases. On the other hand, when the gate voltages of the output transistors decrease, the output voltage VOUT may increase.

According to an example, the load stage 200 may provide a sink current I_SINK to the slew rate compensator 400 when the input voltage VIN is in a falling transition. Based on the provided sink current I_SINK, the load stage 200 may generate a first compensation reference current and a first compensation current obtained by mirroring the first compensation reference current. The load stage 200 may provide the first compensation current to the nodes connected to the gate terminals of the output transistors of the output stage 300. Accordingly, the gate voltages of the output transistors of the output stage 300 may increase and the output voltage VOUT may decrease.

According to an example, the load stage 200 may receive a source current I_SOURCE from the slew rate compensator 400 when the input voltage VIN is in a rising transition. Based on the received source current I_SOURCE, the load stage 200 may generate a second compensation reference current and a second compensation current obtained by mirroring the second compensation reference current. The load stage 200 may receive the second compensation current from the nodes connected to the gate terminals of the output transistors of the output stage 300. Accordingly, the gate voltages of the output transistors of the output stage 300 may decrease and the output voltage VOUT may increase.

In the output stage 300, the gate voltages of the output transistors of the output stage 300 may increase or decrease while voltages of nodes connected to the load stage 200 increase or decrease. When the gate voltages of the output transistors of the output stage 300 increase, the output voltage VOUT of the output stage 300 may decrease. On the other hand, when the gate voltages of the output transistors of the output stage 300 decrease, the output voltage VOUT of the output stage 300 may increase.

By comparing the input voltage VIN and the output voltage VOUT, the slew rate compensator 400 may provide the source current I_SOURCE to the load stage 200, or receive the sink current I_SINK from the load stage 200.

According to an example, when the input voltage VIN is in a rising transition, a point occurs at which the difference between input voltage VIN and the output voltage VOUT exceeds a threshold voltage of a MOS transistor, at which time the slew rate compensator 400 may provide the source current I_SOURCE to the load stage 200. The load stage 200 has a mirroring structure corresponding to the node receiving the source current I_SOURCE, and may allow the second compensation current to flow from the node connected to the gate terminal of the output transistor of the output stage 300. When the second compensation current flows from the node connected to the gate terminal of the output transistor of the output stage 300, the gate voltages of the output transistors of the output stage 300 may decrease and the output voltage VOUT of the output stage 300 may increase.

According to an example, when the input voltage VIN is in a falling transition, the slew rate compensator 400 may decrease the input voltage VIN by a threshold voltage of the internal transistor of the source follower, and a point occurs at which the difference between the reduced input voltage VIN and the output voltage VOUT exceeds a threshold voltage of a MOS transistor, and at this instance, the slew rate compensator 400 may receive the sink current I_SINK from the load stage 200. The load stage 200 has a mirroring structure corresponding to the node which provides the sink current I_SINK, and may allow the first compensation current to flow to the node connected to the gate terminal of the output transistor of the output stage 300. When the first compensation current flows to the node connected to the gate terminal of the output transistor of the output stage 300, the gate voltages of the output transistors of the output stage 300 may increase and the output voltage VOUT of the output stage 300 may decrease.

Hereinafter, a detailed structure of the buffer circuit according to an example of the present disclosure will be described with reference to FIGS. 2 to 6.

Referring to FIGS. 2 to 4, the input stage 100 may include a first input stage 110 comprised of PMOS transistors P_I1 and P_I2 and a second input stage 120 comprised of NMOS transistors N_I1 and N_I2, a first bias circuit 130 providing the first bias current I_B1 to the first input stage 110, and the second bias circuit 140 providing the second bias current I_B2 to the second input stage 120.

The first input stage PMOS transistor P_I1 may have a gate receiving the input voltage VIN, a source connected to the first bias circuit 130 in common with the second input stage PMOS transistor P_I2, and a drain connected to a second differential mirror circuit 220 of the load stage 200. The first input stage PMOS transistor P_I1 may provide the first differential current I_P1 output based on the input voltage VIN to a drain of a second load stage NMOS transistor N_L2 of the second differential mirror circuit 220 of the load stage 200.

The second input stage PMOS transistor P_I2 may have a gate receiving the output voltage VOUT, a source connected to the first bias circuit 130 in common with first input stage PMOS transistor P_I1, and a drain connected to the second differential mirror circuit 220 of the load stage 200. The second input stage PMOS transistor P_I2 may provide the second differential current I_P2 output based on the output voltage VOUT to a drain of the first load stage NMOS transistor N_L1 of the second differential mirror circuit 220 of the load stage 200.

When the input voltage VIN and the output voltage VOUT are the same, the first differential current I_P1 and the second differential current I_P2, both having the same current value, are provided to the load stage 200, and when there is a difference between the input voltage VIN and the output voltage VOUT, a difference is generated in the current values of the first differential current I_P1 and the second differential current_P2 in proportion to the difference between the input voltage VIN and the output voltage VOUT, and the first differential current I_P1 and the second differential current I_P2 are provided, with the difference in the current values, to the load stage 200.

According to an example, when the input voltage VIN changes to ‘L (e.g. VSS)’ in a state where the input voltage VIN and the output voltage VOUT are identically ‘H (e.g. VDD)’, if the voltage between the gate and the source of the first input stage PMOS transistor P_I1, that is, a difference between the input voltage VIN and the power supply voltage VDD is greater than the threshold voltage, the first input stage PMOS transistor P_I1 is turned on, and a current flows, thus, the first differential current I_P1 has a value greater than 0. The first differential current I_P1 may further increase as the input voltage VIN decreases. In this case, the second differential current I_P2 may continue to be 0 during an interval at which the output voltage VOUT does not change at ‘H’.

According to another example, when the input voltage VIN changes to ‘H’ in a state where the input voltage VIN and the output voltage VOUT are identically ‘L’, as the voltage (the difference between the input voltage VIN and the power supply voltage VDD) between the gate and the source of the first input stage PMOS transistor P_I1 gradually decreases, the first differential current I_P1 also decreases accordingly, and when the voltage therebetween is smaller than the threshold voltage, the first differential current I_P1 becomes 0. In this case, the second differential current I_P2 may increase by as much as the first differential current I_P1 decreases. This is because a sum of the first differential current I_P1 and the second differential current I_P2 is equal to the first bias current I_B1.

The second input stage 120 may include a first input stage NMOS transistor N_I1 and a second input stage NMOS transistor N_I2.

The first input stage NMOS transistor N_I1 may have a gate receiving the input voltage VIN, a source connected to the second bias circuit 140 in common with the second input stage NMOS transistor N_I2, and a drain connected to a first differential mirror circuit 210. The first input stage NMOS transistor N_I1 may receive the third differential current I_N1 from a drain of a second load stage PMOS transistor P_L2 of the first differential mirror circuit 210 of the load stage 200 based on the input voltage VIN.

The second input stage NMOS transistor N_I2 may have a gate receiving the output voltage VOUT, a source connected to the second bias circuit 140 in common with the first input stage NMOS transistor N_I1, and a drain connected to the first differential mirror circuit 210 of the load stage 200. The second input stage NMOS transistor N_I2 may receive the fourth differential current I_N2 from a drain of a first load stage PMOS transistor P_L1 of the first differential mirror circuit 210 of the load stage 200 based on the output voltage VOUT.

When the input voltage VIN and the output voltage VOUT are the same, the second input stage 120 receives the third differential current I_N1 and the fourth differential current I_N2, both having the same current value, from the load stage 200, and when there is a difference between the input voltage VIN and the output voltage VOUT, a difference may be generated in the current values of the third differential current I_N1 and the fourth differential current I_N2 in proportion to the difference between the input voltage VIN and the output voltage VOUT. Accordingly, information about the difference between the input voltage VIN and the output voltage VOUT may be provided to the load stage 200.

According to an example, when the input voltage VIN changes to ‘H’ in a state where the input voltage VIN and the output voltage VOUT are identically ‘L’, if the voltage between the gate and the source of the first input stage NMOS transistor N_I1, that is, the difference between the input voltage VIN and the ground voltage VSS, becomes greater than the threshold voltage, the first input stage NMOS transistor N_I1 is turned on and a current flows, and thus, the third differential current I_N1 has a value greater than 0. The third differential current I_N1 may be further increased as the input voltage VIN increases. In this case, the fourth differential current I_N2 may continue to be 0 during an interval at which the output voltage VOUT does not change at ‘L’.

According to another example, when the input voltage VIN changes to ‘L’ in a state where the input voltage VIN and the output voltage VOUT are identically ‘H’, as the voltage between the gate and the source of the first input stage NMOS transistor N_I1 (the difference between the input voltage VIN and the ground voltage VSS) gradually decreases, the third differential current I_N1 also decreases accordingly, and when the voltage therebetween is smaller than the threshold voltage, the third differential current I_N1 becomes 0. In this case, the fourth differential current I_N2 may increase by as much as the third differential current I_N1 decreases. This is because a sum of the third differential current I_N1 and the fourth differential current I_N2 is equal to the second bias current I_B2.

Referring to FIG. 3, the first bias circuit 130 may be disposed between the power supply voltage VDD and the input stage 100. The first bias circuit 130 may be connected to the power supply voltage VDD and the input stage 100. The first bias circuit 130 may provide the first bias current I_B1 to the input stage 100 as a constant current source. The first bias circuit 130 may be configured to include the PMOS transistor P_I3, or may include two of the PMOS transistors P_I3 and P_I4 connected in series in a cascode structure.

The second bias circuit 140 may be disposed between the ground voltage VSS and the input stage 100. The second bias circuit 140 may be connected to the ground voltage VSS and the input stage 100. The second bias circuit 140 may receive the second bias current I_B2 from the input stage 100 as a constant current source. The second bias circuit 140 may be configured to include the NMOS transistor N_I3, or may include two of the NMOS transistors N_I3 and N_I4 connected in series in a cascode structure.

Referring to FIGS. 4 and 6, the load stage 200 may include the first differential mirror circuit 210, the second differential mirror circuit 220, a third bias circuit 230, and a fourth bias circuit 240.

According to an example, the first differential mirror circuit 210 has a cascode structure and may perform a current mirroring operation.

The first differential mirror circuit 210 may serve as a constant current source, supply a current to the input stage 100, the third bias circuit 230 and the fourth bias circuit 240, and apply a voltage to gate terminals of a first output transistor P_O1 and the second output transistor N_O1 of the output stage.

The first differential mirror circuit 210 may include the first load stage PMOS transistor P_L1 and the second load stage PMOS transistor P_L2 which perform a current mirroring operation, and a third load stage PMOS transistor P_L3 and a fourth load stage PMOS transistor P_L4 connected in series to the first load stage PMOS transistor P_L1 and the second load stage PMOS transistor P_L2 to form a cascode structure so that a high voltage gain can be obtained.

In more detail, the first load stage PMOS transistor P_L1 of the first differential mirror circuit 210 may have a gate connected to the third bias circuit 230 in common with the second load stage PMOS transistor P_L2, a drain connected to the third load stage PMOS transistor P_L3, and a source connected to the power supply voltage VDD.

The second load stage PMOS transistor P_L2 of the first differential mirror circuit 210 may have a gate connected to the third bias circuit 230 in common with the first load stage PMOS transistor P_L1, a drain connected to the fourth load stage PMOS transistor P_L4, and a source connected to the power supply voltage VDD.

The third load stage PMOS transistor P_L3 of the first differential mirror circuit 210 may be connected between the third bias circuit 230 and the first load stage PMOS transistor P_L1. The third load stage PMOS transistor P_L3 may include a gate receiving a third bias voltage VB3, a drain that is connected in common with a common gate of the first load stage PMOS transistor P_L1 and the second load stage PMOS transistor P_L2 and where a second node ND2 is disposed that provides a sink current I_SINK to the slew rate compensator 400, and a source connected to the first load stage PMOS transistor P_L1.

The fourth load stage PMOS transistor P_L4 of the first differential mirror circuit 210 may be connected between the fourth bias circuit 240 and the second load stage PMOS transistor P_L2. The fourth load stage PMOS transistor P_L4 may include a gate receiving the third bias voltage VB3, a drain where the first node ND1 connected to the fourth bias circuit 240 and the gate terminal of the first output transistor P_O1 of the output stage 300 is located, and a source connected to the second load stage PMOS transistor P_L2.

According to an example, in the first differential mirror circuit 210, when the second node ND2 provides the sink current I_SINK to the slew rate compensator 400, the gate voltage of the first load stage PMOS transistor P_L1 connected to the second node ND2 may decrease. When the gate voltage of the first load stage PMOS transistor P_L1 decreases, the first compensation reference current may flow through a branch to which the first load stage PMOS transistor P_L1 is connected. When the first compensation reference current flows through the first load stage PMOS transistor P_L1, the first compensation current which is obtained by mirroring the first compensation reference current may flow through a branch to which the second load stage PMOS transistor P_L2 having a mirroring structure with the first load stage PMOS transistor P_L1 is connected. Here, the first compensation current may be an additional current added to the bias current flowing when the second load stage PMOS transistor P_L2 is in a normal state. When the first compensation current is added to and flows through the first node ND1 from the second load stage PMOS transistor P_L2, the voltage PPG of the first node ND1 may increase. In addition, the voltage PNG of the third node ND3 connected to the first node ND1 centering on the elements of the fourth bias circuit 240 may also increase. That is, the gate voltage PPG of the first output transistor P_O1 connected to the first node ND1 and the gate voltage PNG of the second output transistor N_O1 connected to the third node ND3 may increase. As will be described below, the first output transistor P_O1 consists of the PMOS transistor, and when the gate voltage PPG increases, a push current I_Push flowing from the first output transistor P_O1 to the output terminal may decrease. The second output transistor N_O1 consists of the NMOS transistor, and when the gate voltage PNG increases, a pull current I_Pull flowing from the output terminal to the second output transistor N_O1 may increase. Therefore, because the push current I_Push provided to the output terminal decreases and the pull current I_Pull provided from the output terminal increases, the output voltage VOUT output from the output terminal rapidly decreases, thereby becoming able to rapidly follow the falling transition of the input voltage. According to an example, the second differential mirror circuit 220 has a cascode structure and may perform a current mirroring operation.

The second differential mirror circuit 220 may serve as a constant current source, receive a current from the third bias circuit 230 and the fourth bias circuit 240, and apply a voltage to the gate terminals of the first output transistor P_O1 and the second output transistor N_O1 of the output stage.

The second differential mirror circuit 220 may include the first load stage NMOS transistor N_L1 and the second load stage NMOS transistor N_L2 which perform a current mirroring operation, and a third load stage NMOS transistor N_L3 and a fourth load stage NMOS transistor N_L4 connected in series to the first load stage NMOS transistor N_L1 and the second load stage NMOS transistor N_L2 to form a cascode structure so that a high voltage gain can be obtained.

In more detail, the first load stage NMOS transistor N_L1 of the second differential mirror circuit 220 may have a gate connected to the third bias circuit 230 in common with the second load stage NMOS transistor N_L2, a drain connected to the third load stage NMOS transistor N_L3, and a source connected to the ground voltage VSS.

The second load stage NMOS transistor N_L2 of the second differential mirror circuit 220 may have a gate connected to the third bias circuit 230 in common with the first load stage NMOS transistor N_L1, a drain connected to the fourth load stage NMOS transistor N_L4, and a source connected to the ground voltage VSS.

The third load stage NMOS transistor N_L3 of the second differential mirror circuit 220 may be connected between the first load stage NMOS transistor N_L1 and the third bias circuit 230. The third load stage NMOS transistor N_L3 may have a gate receiving a fourth bias voltage VB4, a drain in which a fourth node ND4 connected to the gate of the first load stage NMOS transistor N_L1 and receiving the source current I_SOURCE from the slew rate compensator 400 is positioned, and a source connected to the first load stage NMOS transistor N_L1.

The fourth load stage NMOS transistor N_L4 of the second differential mirror circuit 220 may be connected between the second load stage NMOS transistor N_L2 and the fourth bias circuit 240. The fourth load stage NMOS transistor N_L4 may have a gate receiving the fourth bias voltage VB4, a drain in which a third node ND3 connected to the fourth bias circuit 240 and a gate terminal of the second output transistor N_O1 is positioned, and a source connected to the second load stage NMOS transistor N_L2.

According to an example, in the second differential mirror circuit 220, when the fourth node ND4 receives the source current I_SOURCE from the slew rate compensator 400, the gate voltage of the first load stage NMOS transistor N_L1 connected to the fourth node ND4 may increase. When the gate voltage of the first load stage NMOS transistor N_L1 increases, the second compensation reference current may flow through a branch to which the first load stage NMOS transistor N_L1 is connected. When the second compensation reference current flows through the first load stage NMOS transistor N_L1, the second compensation current which is obtained by mirroring the second compensation reference current may flow through a branch to which the second load stage NMOS transistor N_L2 having a mirroring structure with the first load stage NMOS transistor N_L1 is connected. Here, the second compensation current may be an additional current added to the bias current flowing when the second load stage NMOS transistor N_L2 is in a normal state. When the second compensation current is added to and flows through the second load stage NMOS transistor N_L2 from the third node ND3, the voltage PNG of the third node ND3 may decrease. In addition, the voltage PPG of the first node ND1 connected to the third node ND3 centering on the elements of the fourth bias circuit 240 may also decrease. That is, the gate voltage PPG of the first output transistor P_O1 connected to the first node ND1 and the gate voltage PNG of the second output transistor N_O1 connected to the third node ND3 may decrease. As will be described below, the first output transistor P_O1 comprises the PMOS transistor, and when the gate voltage PPG decreases, the push current I_Push flowing from the first output transistor P_O1 to the output terminal may increase. The second output transistor N_O1 comprises the NMOS transistor, and when the gate voltage PNG decreases, the pull current I_Pull flowing from the output terminal to the second output transistor N_O1 may decrease. Therefore, the push current I_Push supplied to the output terminal increases and the pull current I_Pull supplied from the output terminal decreases, resulting in a sharp increase in the output voltage VOUT at the output terminal to quickly follow the rising transition of the input voltage.

The third bias current 230 may include a fifth load stage PMOS transistor P_L5 receiving a fifth bias voltage VB5, and a fifth load stage NMOS transistor N_L5 receiving a sixth bias voltage VB6. The third bias current 230 may be positioned between the first differential mirror circuit 210 and the second differential mirror circuit 220. The third bias current 230 may control an operation in a static state and an amplification operation of the first differential mirror circuit 210 and the second differential mirror circuit 220. In addition, the third bias current 230 may be used as a floating current source, and may regulate voltages of the second node ND2 and the fourth node ND4 with a high impedance.

The fourth bias current 240 may include a sixth load stage PMOS transistor P_L6 receiving a seventh bias voltage VB7, and a sixth load stage NMOS transistor N_L6 receiving an eighth bias voltage VB8. The fourth bias current 240 may be connected between the first differential mirror circuit 210 and the second differential mirror circuit 220. The fourth bias current 240 may control an operation in a static state and an amplification operation of the first differential mirror circuit 210 and the second differential mirror circuit 220. In addition, the fourth bias current 240 may be used as a floating current source, and may regulate voltages of the first node ND1 and the third node ND3 with a high impedance.

Referring to FIG. 5, according to another example, the first differential mirror circuit 210 may not have the cascode structure, and may perform the current mirroring operation. In addition, the second differential mirror circuit 220 may not have the cascode structure, and may perform the current mirroring operation.

The first differential mirror circuit 210 and the second differential mirror circuit 220, which are illustrated in FIG. 5, may operate similarly to the first differential mirror circuit 210 and the second differential mirror circuit 220, which are illustrated in FIG. 4, except for the cascode structure.

When the first differential mirror circuit 210 and the second differential mirror circuit 220 have a cascode structure, the output impedance of an element used as a constant current element is increased, which has the effect of obtaining a high voltage gain. However, there are shortcomings that many elements such as transistors are used, which complicates the process and increases the area size of the layout. Therefore, the first differential mirror circuit 210 and the second differential mirror circuit 220 illustrated in FIG. 4 or FIG. 5 may be included in the configuration depending on whether the purpose is to obtain a high voltage gain or to reduce the area size of the layout by simplifying the process.

Referring to FIGS. 4 and 6 again, the slew rate compensator 400 may include a comparator 410, a source follower 420, a source current circuit 430, and a sink current circuit 440. In addition, the slew rate compensator 400 may further include a slew rate compensation switch 450, a first control circuit 460, and a second control circuit 470.

The comparator 410 may include a first comparator N_COMP and a second comparator P_COMP.

The first comparator N_COMP may compare a difference between the input voltage VIN and the output voltage VOUT and enter an ON operating state or an OFF operating state based on the difference between the input voltage VIN and the output voltage VOUT.

The first comparator N_COMP may include an NMOS transistor having a gate receiving the input voltage VIN; a drain directly connected to the source current circuit 430 or connected to the source current circuit 430 with a first slew rate compensation switch P_SW1 interposed therebetween; and a source receiving the output voltage VOUT.

The second comparator P_COMP may compare a difference between the reduced input voltage VIN output from the source follower 420 and the output voltage VOUT and enter an ON operating state or an OFF operating state based on the difference between the reduced input voltage VIN and the output voltage VOUT.

The second comparator P_COMP may include a PMOS transistor having a gate receiving the reduced input voltage output from the source follower 420; a drain directly connected to the sink current circuit 440 or connected to the sink current circuit 440 with a second slew rate compensation switch N_SW1 interposed therebetween; and a source receiving the output voltage VOUT in common with the first comparator N_COMP.

According to an example, because the second comparator P_COMP compares the reduced input voltage VIN, as the gate voltage, to the output voltage VOUT, a channel of the internal PMOS transistor of the second comparator P_COMP may be more rapidly formed and the second comparator P_COMP may rapidly enter the ON operating state. In addition, by decreasing a minimal operating voltage with respect to the falling transition of the input voltage VIN, it is possible to use a range of the input voltage VIN more widely.

According to an example, unlike the PMOS transistor of the second comparator P_COMP, the NMOS transistor of the first comparator N_COMP may include a body connected in common with the source and configured to receive the output voltage VOUT.

Even if the same output voltage VOUT is provided to the source and the body and a body voltage is changed, the NMOS transistor of the first comparator N_COMP may use the threshold voltage of the transistor constantly. When regulating the body voltage of the NMOS transistor of the first comparator N_COMP, the NMOS transistor needs to be separated by a deep N-well area, but conversely, the area size of the layout can be reduced by using the N-well region of a regular PMOS transistor that applies its body voltage to the power supply voltage VDD. On the other hand, when regulating the body voltage of the PMOS transistor of the second comparator P_COMP, the N-well region of a regular PMOS transistor having the body voltage applied as the power supply voltage VDD must be separated, therefore, the area size of the layout may become expanded. Accordingly, as described above, the NMOS transistor of the first comparator N_COMP may connect the body and the source in common, and the PMOS transistor of the second comparator P_COMP may not connect the body and the source in common.

The source follower 420 may reduce the input voltage VIN by the threshold voltage of the MOS transistor and then provide it to the gate terminal of the second comparator P_COMP.

The source follower 420 may include a first source follower NMOS transistor N_SF1 having a gate receiving the input voltage VIN, a drain directly connected to the power supply voltage VDD or connected to the power supply voltage VDD with a third slew rate compensation switch P_SW2 interposed therebetween, a source connected to a gate of the PMOS transistor of the second comparator P_COMP, and a body connected in common with the source. In addition, the source follower 420 may include a second source follower NMOS transistor N_SF2 having a gate receiving a ninth bias voltage VB9, a drain connected to the source of the first source follower NMOS transistor N_SF1, and a source connected to the first control circuit 460, and is configured to provide a bias current.

The source follower 420 may reduce the input voltage VIN by the threshold voltage of the first source follower NMOS transistor N_SF1 and then provide it to the gate terminal of the second comparator P_COMP.

According to an example, when a magnitude of the input voltage VIN exceeds the threshold voltage of the NMOS transistor of the first comparator N_COMP and grows greater than the output voltage VOUT, the first comparator N_COMP enters the ON operating state and the second comparator P_COMP enters the OFF operating state. Accordingly, the source current circuit 430 may be activated and the sink current circuit 440 may be deactivated. The source current circuit 430 may be activated and may provide the source current I_SOURCE to the load stage 200.

According to another example, when a magnitude of the input voltage VIN output from the source follower 420 becomes smaller than the output voltage VOUT so that it can exceed the threshold voltage of the PMOS transistor of the second comparator P_COMP, the first comparator N_COMP enters the OFF operating state and the second comparator P_COMP enters the ON operating state. Accordingly, the source current circuit 430 may be deactivated and the sink current circuit 440 may be activated. When the sink current circuit 440 is activated, it is possible to receive the sink current I_SINK from the load stage 200.

The first control circuit 460 may control the magnitude of the current flowing through the source follower 420.

The first control circuit 460 may include a first control NMOS transistor N_C having a gate receiving a tenth bias voltage VB10, a drain connected to the second source follower NMOS transistor N_SF2 of the source follower 420, and a source connected to the ground voltage VSS.

According to an example, the tenth bias voltage VB10 may be a value which is changed according to the rising transition or the falling transition of the input voltage VIN, and may be the gate voltage PNG of the second output transistor N_O1. For example, the tenth bias voltage VB10 may fall to a low level when the input voltage VIN is in the rising transition, maintain a level of the threshold voltage of the second output transistor N_O1 when the input voltage VIN and the output voltage VOUT are equal and in a stable state, and rise to a high level when the input voltage VIN is in the falling transition.

When the input voltage VIN is in the falling transition, the first control circuit 460 may allow the current supplied from the source follower 420 to be supplied as it is so that the output voltage VOUT rapidly follows the input voltage, and in other cases except the falling transition of the input voltage VIN, the first control circuit 460 may reduce the magnitude of the current flowing through the source follower 420 so that unnecessary consumption of the electric power can be reduced.

The second control circuit 470 may be disposed between the power supply voltage VDD and the source follower 420, and may control the voltage output from the source follower 420 (hereinafter, a corrected input voltage). The corrected input voltage may mean the voltage obtained by reducing the input voltage VIN by the threshold voltage of the MOS transistor.

The second control circuit 470 may include a second control PMOS transistor P_C2 having a gate receiving a twelfth bias voltage VB12, a drain connected to a first control PMOS transistor P_C1, and a source connected to the power supply voltage VDD. In addition, the second control circuit 470 may include the first control PMOS transistor P_C1 having a gate receiving an eleventh bias voltage VB11, a drain connected to the output of the source follower 420, and a source connected to the second control PMOS transistor P_C2. The first control PMOS transistor P_C1 is a constant current source and may supply the current to the node connected to the output of the source follower 420.

The eleventh bias voltage VB11 is determined to be a random value for the drive of the first control PMOS transistor P_C1, is a value which is changed according to the rising transition or the falling transition of the input voltage VIN, and may be the gate voltage PPG of the first output transistor P_O1. For example, the twelfth bias voltage VB12 may fall to a low level when the input voltage VIN is in the rising transition, and maintain a level of a value obtained by subtracting the threshold voltage of the first output transistor P_O1 from the power supply voltage VDD when the input voltage VIN and the output voltage VOUT are equal and in a stable state, and rise to a high level when the input voltage VIN is in the falling transition. When the input voltage VIN is in the falling transition, the second control circuit 470 may control to disconnect between the output of the source follower 420 and the power supply voltage VDD so that the corrected input voltage output from the source follower 420 can be decreased and the second comparator P_COMP can enter the ON operating state.

In addition, and in other cases except the falling transition of the input voltage VIN, the second control circuit 470 may control to allow the connection between the output of the source follower 420 and the power supply voltage VDD so that the current by the power supply voltage VDD can be provided to the node connected to the output of the source follower 420, and the corrected input voltage output from the source follower 420 can be increased, thereby the second comparator P_COMP enters the OFF operating state.

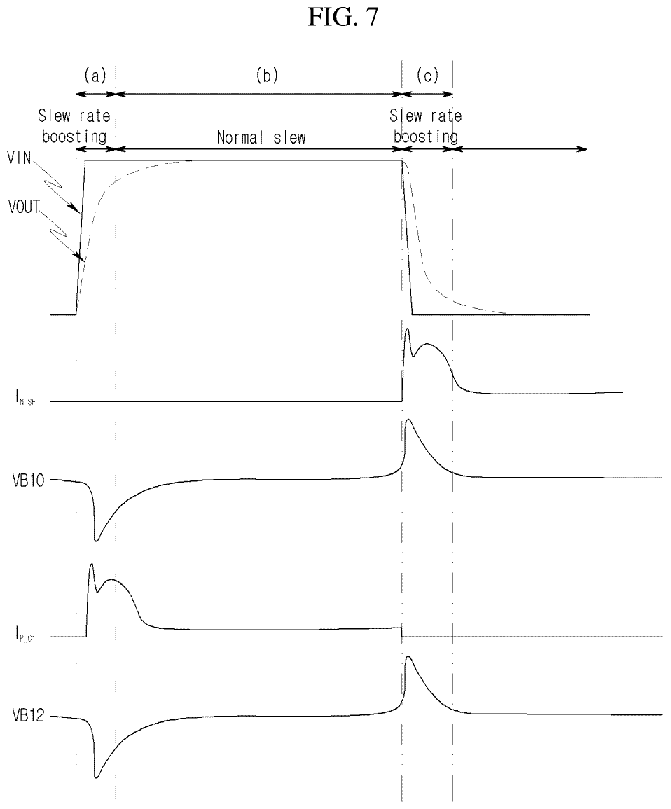

The detailed operation of the first control circuit 460 and the second control circuit 470 will be described with reference to FIG. 7 below. The source current circuit 430 may be directly connected to the first comparator N_COMP or may be connected to the first comparator N_COMP with the first slew rate compensation switch P_SW1 interposed therebetween.

The source current circuit 430 may be connected to the load stage 200 and may provide the source current I_SOURCE to the load stage 200. The source current circuit 430 may provide the source current I_SOURCE to the load stage 200 based on the difference between the input voltage VIN and the output voltage VOUT.

The source current circuit 430 may be activated in the ON operating state of the first comparator N_COMP.

The source current circuit 430 may include first and second source PMOS transistors P_SR1 and P_SR2.

In more detail, the first source PMOS transistor P_SR1 of the source current circuit 430 may have a gate which is directly connected to the first comparator N_COMP, or connected to the first comparator N_COMP with the first slew rate compensation switch P_SW1 interposed therebetween, a drain connected in common with the gate, and a source receiving the power supply voltage VDD.

The second source PMOS transistor P_SR2 of the source current circuit 430 may have a gate connected in common with the gate of the first source PMOS transistor P_SR1, a drain connected to a fourth node ND4 of the load stage 200 having a mirroring structure and corresponding to a third node ND3 of the load stage 200 connected to the gate terminal of the second output transistor N_O1, and a source receiving the power supply voltage VDD.

The first source PMOS transistor P_SR1 of the source current circuit 430 may be connected to the first comparator N_COMP and a source reference current may flow through the first source PMOS transistor P_SR1 of the source current circuit 430. The second source PMOS transistor P_SR2 of the source current circuit 430 may have a current mirroring structure with respect to the first source PMOS transistor P_SR1, and may mirror the source reference current, thereby the source current I_SOURCE may flow through the second source PMOS transistor P_SR2 of the source current circuit 430.

The sink current circuit 440 may be directly connected to the second comparator P_COMP or connected to the second comparator P_COMP with a second slew rate compensation switch N_SW1 interposed therebetween.

The sink current circuit 440 may be connected to the load stage 200 and may receive the sink current I_SINK from the load stage 200. The sink current circuit 440 may receive the sink current I_SINK from the load stage 200 based on the difference between the reduced input voltage VIN and the output voltage VOUT.

The sink current circuit 440 may be activated in the ON operating state of the second comparator P_COMP.

The sink current circuit 440 may include first and second sink NMOS transistors N_SR1 and N_SR2.

In more detail, the first sink NMOS transistor N_SR1 of the sink current circuit 440 may have a gate connected to the second comparator P_COMP or connected to the second comparator P_COMP with the second slew rate compensation switch N_SW1 interposed therebetween, a drain connected in common with the gate, and a source receiving the ground voltage VSS.

The second sink NMOS transistor N_SR2 of the sink current circuit 440 may have a gate connected in common with the gate of the first sink NMOS transistor N_SR1, a drain connected to a second node ND2 of the load stage 200 having a mirroring structure and corresponding to the first node ND1 of the load stage 200 connected to a gate terminal of the first output transistor P_O1, and a source receiving the ground voltage VSS.

The first sink NMOS transistor N_SR1 of the sink current circuit 440 may be connected to the second comparator P_COMP and the sink reference current may flow through the first sink NMOS transistor N_SR1 of the sink current circuit 440. The second sink NMOS transistor N_SR2 of the sink current circuit 440 may have a current mirroring structure with respect to the first sink NMOS transistor N_SR1, and may mirror the sink reference current, thereby the sink current I_SINK may flow through the second sink NMOS transistor N_SR2 of the sink current circuit 440.

The slew rate compensation switch 450 includes first and second slew rate compensation switches P_SW1 and N_SW1, and may determine whether to operate each of the source current circuit 430 and the sink current circuit 440. In addition, the slew rate compensation switch 450 includes the third slew rate compensation switch P_SW2 and may determine whether to operate the source follower 420.

The first slew rate compensation switch P_SW1 may be positioned between the first comparator N_COMP and the source current circuit 430 to be connected therebetween. The first slew rate compensation switch P_SW1 may block the current flowing between the source current circuit 430 and the first comparator N_COMP based on a first switch signal SW1. In addition, the first slew rate compensation switch P_SW1 may control an intensity of the current flowing between the source current circuit 430 and the first comparator N_COMP based on the first switch signal SW1. The second slew rate compensation switch N_SW1 may be positioned between the second comparator P_COMP and the sink current circuit 440 to be connected therebetween. The second slew rate compensation switch N_SW1 may block the current flowing between the sink current circuit 440 and the second comparator P_COMP based on a second switch signal SW2. In addition, the second slew rate compensation switch N_SW1 may control an intensity of the current flowing between the sink current circuit 440 and the second comparator P_COMP based on the second switch signal SW2. The third slew rate compensation switch P_SW2 may be positioned between the power supply voltage VDD and the source follower 420 to be connected therebetween. The third slew rate compensation switch P_SW2 may block the current flowing between the power supply voltage VDD and the source follower 420 based on a third switch signal SW3. In addition, the third slew rate compensation switch P_SW2 may control an intensity of the current flowing between the power supply voltage VDD and the source follower 420 based on the third switch signal SW3.

The output stage 300 may include the first and second output transistors P_O1 and N_O1 and first and second compensation capacitors C1 and C2.

The first output transistor P_O1 may have a gate connected to the first node ND1 of the first differential mirror circuit 210 of the load stage 200, a source connected to the power supply voltage VDD, and a drain connected to the output voltage VOUT. Based on the voltage PPG of the first node ND1 connected to a gate of the first output transistor P_O1, the current flowing through the first output transistor P_O1 may be changed.

The second output transistor N_O1 may have a gate connected to the third node ND3 of the second differential mirror circuit 220 of the load stage 200, a source connected to the ground voltage VSS, and a drain connected to the output voltage VOUT. Based on the voltage PNG of the third node ND3 connected to the gate of the second output transistor N_O1, the current flowing through the second output transistor N_O1 may be changed.

When the gate voltages of the first and second output transistors P_O1 and N_O1 increase, the output voltage VOUT of the output stage 300 may decrease. On contrary, when the gate voltages of the first and second output transistors P_O1 and N_O1 decrease, the output voltage VOUT of the output stage 300 may increase.

In more detail, according to an example, the first output transistor P_O1 comprises a PMOS transistor, and when the gate voltage PPG of the first output transistor P_O1 increases, the push current I_Push flowing from the first output transistor P_O1 to the output terminal may decrease. The second output transistor N_O1 comprises an NMOS transistor, and when the gate voltage PNG of the second output transistor N_O1 increases, the pull current I_Pull flowing from the output terminal to the second output transistor N_O1 may increase. Therefore, because the push current I_Push provided to the output terminal decreases and the pull current I_Pull provided from the output terminal increases, the output voltage VOUT output from the output terminal rapidly decreases, thereby becoming able to rapidly follow the falling transition of the input voltage.

In addition, according to another example, the first output transistor P_O1 comprises a PMOS transistor, and when the gate voltage PPG of the first output transistor P_O1 decreases, the push current I_Push flowing from the first output transistor P_O1 to the output terminal may increase. The second output transistor N_O1 comprises an NMOS transistor, and when the gate voltage PNG of the second output transistor N_O1 decreases, the pull current I_Pull flowing from the output terminal to the second output transistor N_O1 may decrease. Therefore, because the push current I_Push provided to the output terminal increases and the pull current I_Pull provided from the output terminal decreases, the output voltage VOUT output from the output terminal rapidly increases, thereby becoming able to rapidly follow the rising transition of the input voltage.

The first compensation capacitor C1 may have one end connected to the output voltage VOUT and the other end connected to the first differential mirror circuit 210. The second compensation capacitor C2 may have one end connected to the output voltage VOUT and the other end connected to the second differential mirror circuit 220. The slew rate of the output voltage VOUT with respect to the input voltage VIN may increase or decrease based on the charge and discharge rates of the first and second compensation capacitors C1 and C2.

FIG. 7 is a timing diagram of the slew rate compensator 400 according to an example of the present disclosure. For your information, FIG. 7 may be described with reference to FIGS. 6 and 7 together.

In FIG. 7, intervals (a), (b), and (c) may mean an interval of the rising transition at which the input voltage VIN is in the rising transition, an interval at which the input voltage VIN and the output voltage VOUT are equal and in a stable state, and an interval at which the input voltage VIN is in the falling transition, respectively. In addition, in FIG. 7, I_{N_SF} means a current flowing through the source follower 420, the VB10 and VB12 mean the tenth and the twelfth bias voltages, respectively, and I_{P_C1} means a current flowing through the first control PMOS transistor P_C1.

First, referring to the interval (a) in FIG. 7, it is possible to confirm that when the input voltage VIN is in the rising transition, the tenth bias voltage VF10 and the twelfth bias voltage VB12 fall to a low level. Accordingly, the first control NMOS transistor N_C of the first control circuit 460 may perform an OFF operation and the second control PMOS transistor P_C2 of the second control circuit 470 may perform an ON operation.

That is, when the input voltage VIN is in the rising transition, it is possible to control the first and second control PMOS transistors P_C1 and P_C2 of the second control circuit 470 to be turned on so that the current can be provided to the node connected to the output of the source follower 420, and accordingly, the corrected input voltage output from the source follower 420 to increase so that the second comparator P_COMP is turned off.

At the same time, the first control NMOS transistor N_C of the first control circuit 460 may be turned off so that a magnitude of the current flowing through the source follower 420 can be reduced, thereby unnecessary consumption of the electric power can be reduced.

Next, referring to the interval (b) in FIG. 7, it is possible to confirm that when the input voltage VIN and the output voltage VOUT are the same, the tenth bias voltage VB10 is at the level of the threshold voltage of the second output transistor N_O1, and the twelfth bias voltage VB12 is maintained at a level of a value obtained by subtracting the threshold voltage of the first output transistor P_O1 from the power supply voltage VDD. That is, in the interval (b) in FIG. 7, the transistors of each of the first control circuit 460 and the second control circuit 470 may operate in the same way as the operation of each of the transistors in the interval (a) in FIG. 7.

Next, referring to the interval (c) in FIG. 7, it is possible to confirm that when the input voltage VIN is in the falling transition, the tenth bias voltage VB10 and the twelfth bias voltage VB12 rise to a high level. Accordingly, the first control NMOS transistor N_C of the first control circuit 460 may perform an ON operation, and the second control PMOS transistor P_C2 of the second control circuit 470 may perform an OFF operation.

That is, when the input voltage VIN is in the falling transition, it is possible to control the first and second PMOS transistors P_C1 and PC2 of the second control circuit 470 to be turned off so that the current flowing from the power supply voltage VDD to the node connected to the output of the source follower 420 can be blocked, and the corrected input voltage output from the source follower 420 to decrease so that the second comparator P_COMP is turned on.

At the same time, the first control NMOS transistor N_C of the first control circuit 460 may be turned on so that a magnitude of the current flowing through the source follower 420 can become increased. In other words, the first control NMOS transistor N_C of the first control circuit 460 may grow the magnitude of the current flowing through the source follower 420 increased so that the output voltage VOUT can rapidly follow the input voltage VIN.

Hereinafter, a method for improving the slew rate of the buffer circuit 1000 according to various embodiments of the present disclosure will be described.

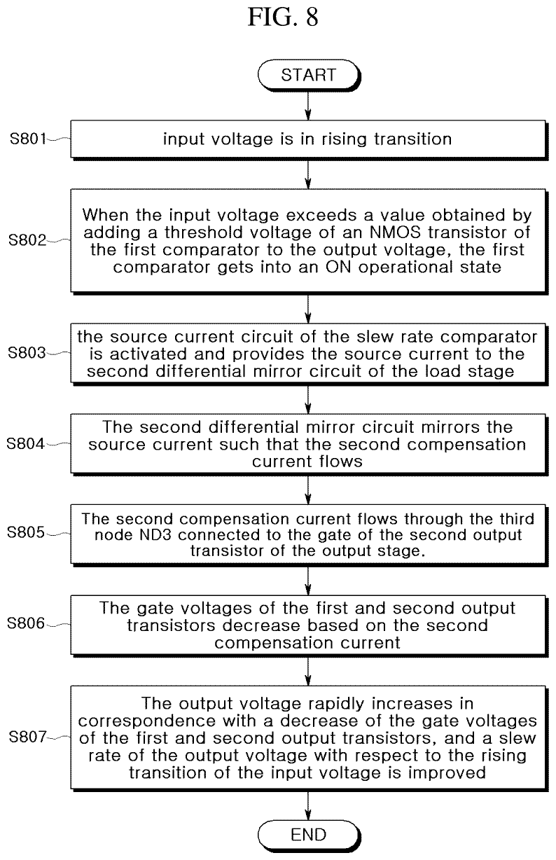

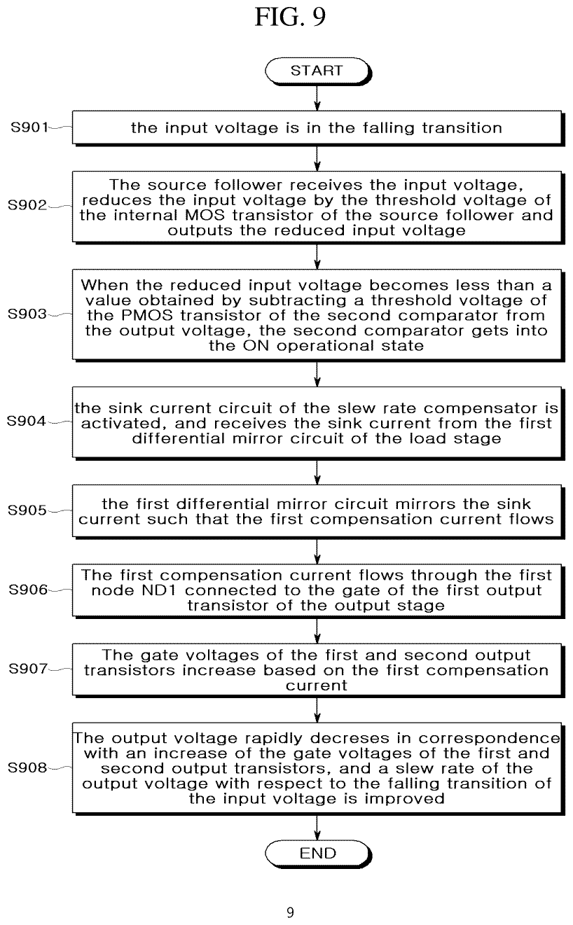

FIG. 8 is a flowchart illustrating a method for improving the slew rate of the output voltage with respect to the rising transition of the input voltage according to an example of the present disclosure, and FIG. 9 is a flowchart illustrating a method for improving the slew rate of the output voltage with respect to the falling transition of the input voltage according to another example of the present disclosure.

A slew-rate compensating operation which rapidly increases the output voltage VOUT when the input voltage VIN rises and a slew-rate compensating operation which rapidly decreases the output voltage VOUT when the input voltage VIN falls are separately described.

First, referring to FIG. 8, the slew-rate compensating operation which rapidly increases the output voltage VOUT when the input voltage VIN rises will be described.

In operations S801 and S802, when the input voltage is in the rising transition, that is, when the input voltage VIN changes to ‘H (e.g. VDD)’ in a state where the input voltage VIN and the output voltage VOUT are identically ‘L (e.g. VSS)’, there occurs a time point when a magnitude of the input voltage VIN grows equal to or bigger than a threshold voltage of the MOS transistor than does a magnitude of the output voltage VOUT, and at this instance, the first comparator N_COMP may enter the ON operating state and the second comparator P_COMP may enter the OFF operating state. Accordingly, the source current circuit 430 may be activated, and the sink current circuit 440 may be deactivated.

In an operation S803, when the source current circuit 430 is activated, the first source PMOS transistor P_SR1 of the source current circuit 430 may be connected to the first comparator N_COMP and the source reference current may flow through the first source PMOS transistor P_SR1 of the source current circuit 430. The second source PMOS transistor P_SR2 of the source current circuit 430 may have a current mirroring structure with respect to the first source PMOS transistor P_SR1, and may mirror the source reference current, thereby the source current I_SOURCE can flow through the second source PMOS transistor P_SR2 of the source current circuit 430. The source current circuit 430 may provide the source current I_SOURCE to the second differential mirror circuit 220 of the load stage 200.

In an operation S804, when the second differential mirror circuit 220 receives the source current I_SOURCE from the slew rate compensator 400 at the fourth node ND4, the gate voltage of the first load stage NMOS transistor N_L1 connected to the fourth node ND4 may increase. When the gate voltage of the first load stage NMOS transistor N_L1 increases, the second compensation reference current may flow through the branch to which the first load stage NMOS transistor N_L1 is connected. When the second compensation reference current flows through the first load stage NMOS transistor N_L1, the second compensation current which is obtained by mirroring the second compensation reference current may flow through the branch to which the second load stage NMOS transistor N_L2 having a mirroring structure with the first load stage NMOS transistor N_L1 is connected. Here, the second compensation current may be an additional current added to the bias current flowing when the second load stage NMOS transistor N_L2 is in a normal state.

In operations S805 and S806, when the second compensation current is added to and flows through the second load stage NMOS transistor N_L2 from the third node ND3, the voltage of the third node ND3 may more rapidly decrease. In addition, the voltage of the first node ND1 connected to the third node ND3 centering on the elements of the fourth bias circuit 240 may also decrease. That is, the gate voltage of the first output transistor P_O1 connected to the first node ND1 and the gate voltage of the second output transistor N_O1 connected to the third node ND3 may more rapidly decrease.

In an operation S807, when the gate voltages of the first and second output transistors P_O1 and N_O1 decrease, in case of the first output transistor P_O1 which consists of the PMOS transistor, the push current I_Push flowing from the first output transistor P_O1 to the output terminal may increase, and in case of the second output transistor N_O1 which consists of the NMOS transistor, the pull current I_Pull flowing from the output terminal to the second output transistor N_O1 may decrease. Therefore, because the push current I_Push provided to the output terminal increases and the pull current I_Pull provided from the output terminal decreases, the output voltage VOUT output from the output terminal rapidly increases, thereby becoming able to rapidly follow the rising transition of the input voltage.

Next, referring to FIG. 9, the slew-rate compensating operation which rapidly decreases the output voltage VOUT when the input voltage VIN falls will be described.

First, in operations S901 to S902, when the input voltage is in the falling transition, that is, when the input voltage VIN changes to ‘L (e.g. VSS)’ in a state where the input voltage VIN and the output voltage VOUT are identically ‘H (e.g. VDD)’, the input voltage may be output while having a more reduced value than the threshold voltage of the internal MOS transistor of the source follower 420 by the source follower 420.

In an operation S903, there occurs a time point when a magnitude of the reduced input voltage VIN becomes equal to or less than a threshold voltage of the MOS transistor than does a magnitude of the output voltage VOUT, and at this instance, the first comparator N_COMP may enter the OFF operating state and the second comparator P_COMP may enter the ON operating state. Accordingly, the sink current circuit 440 may be activated, and the source current circuit 430 may be deactivated.

In an operation S904, when the sink current circuit 440 is activated, the first sink NMOS transistor N_SR1 of the sink current circuit 440 is connected to the second comparator P_COMP and the sink current I_SINK may flow through the first sink NMOS transistor N_SR1 of the sink current circuit 440. The second sink NMOS transistor N_SR2 of the sink current circuit 440 has the current mirroring structure with respect to the first sink NMOS transistor N_SR1, and may mirror the sink reference current and the sink current I_SINK may flow through the second sink NMOS transistor N_SR2 of the sink current circuit 440. The sink current circuit 440 may receive the sink current I_SINK from the first differential mirror circuit 210 of the load stage 200.

In an operation S905, in the first differential mirror circuit 210, when the second node ND2 provides the sink current I_SINK to the slew rate compensator 400, the gate voltage of the first load stage PMOS transistor P_L1 connected to the second node ND2 may decrease. When the gate voltage of the first load stage PMOS transistor P_L1 decreases, the first compensation reference current may flow through the branch to which the first load stage PMOS transistor P_L1 is connected. When the first compensation reference current flows through the first load stage PMOS transistor P_L1, the first compensation current which is obtained by mirroring the first compensation reference current may flow through the branch to which the second load stage PMOS transistor P_L2 having a mirroring structure with the first load stage PMOS transistor P_L1 is connected. Here, the first compensation current may be an additional current added to the bias current flowing when the second load stage PMOS transistor P_L2 is in a normal state.

In operations S906 and S907, when the first compensation current is added to and flows through the first node ND1 from the second load stage PMOS transistor P_L2, the voltage of the first node ND1 may increase. In addition, the voltage of the third node ND3 connected to the first node ND1 centering on the elements of the fourth bias circuit 240 may also increase. That is, the gate voltage of the first output transistor P_O1 connected to the first node ND1 and the gate voltage of the second output transistor N_O1 connected to the third node ND3 may increase.

In an operation S908, when the gate voltages of the first and the second output transistors P_O1 and N_O1 increase, in case of the first output transistor P_O1 which consists of the PMOS transistor, the push current I_Push flowing from the first output transistor P_O1 to the output terminal may decrease, and in case of the second output transistor N_O1 which consists of the NMOS transistor, the pull current I_Pull flowing from the output terminal to the second output transistor N_O1 may increase. Therefore, because the push current I_Push provided to the output terminal decreases and the pull current I_Pull provided from the output terminal increases, the output voltage VOUT output from the output terminal rapidly decreases, thereby becoming able to rapidly follow the falling transition of the input voltage.

As described above, the buffer circuit according to various embodiments of the present disclosure may provide a circuit that improves the slew rate, alleviate size constraints, and be implemented at low power.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A buffer circuit configured to generate an output voltage according to an input voltage, comprising:
an input stage configured to provide first and second differential currents to a load stage or receive third and fourth differential currents from the load stage based on a difference between the input voltage and the output voltage;
a load stage configured to apply gate voltages to first and second output transistors of an output stage based on the first through fourth differential currents;
the output stage configured to regulate the output voltage based on the gate voltages applied to the first and the second output transistors; and
a slew rate compensator configured to regulate the gate voltages of the first and second output transistors by providing a source current to the load stage or receiving a sink current from the load stage,
wherein the slew rate compensator comprises:
a source follower configured to output a corrected input voltage obtained by reducing the input voltage by a threshold voltage of a MOS transistor; and
a first control circuit configured to control a magnitude of the corrected input voltage output from the source follower.

2. The buffer circuit of claim 1, wherein the first control circuit comprises a first control NMOS transistor having a drain connected to the source follower; a source connected to a ground voltage; and a gate to which a gate voltage of the second output transistor is applied.

3. The buffer circuit of claim 1, wherein the slew rate compensator further comprises:
a first comparator configured to enter an ON operating state or an OFF operating state based on the difference between the input voltage and the output voltage;
a second comparator configured to enter an ON operating state or an OFF operating state based on a difference between the corrected input voltage and the output voltage;
a source current circuit configured to provide the source current to the load stage;
a sink current circuit configured to receive the sink current from the load stage;
a slew rate compensation switch configured to determine whether the source current circuit or the sink current circuit is operating; and
a second control circuit configured to control the corrected input voltage output from the source follower.

4. The buffer circuit of claim 3, wherein the second control circuit comprises:
a first control PMOS transistor configured to operate as a current source; and
a second control PMOS transistor having a drain connected to the first control PMOS transistor; a source connected to a power supply voltage; and a gate to which a gate voltage of the first output transistor is applied.

5. The buffer circuit of claim 4, wherein the first comparator comprises an NMOS transistor having a gate connected to the input voltage; a drain connected to the source current circuit; and a source connected to the output voltage,
wherein the second comparator comprises a PMOS transistor having a gate connected to the corrected input voltage output from the source follower; a drain connected to the sink current circuit; and a source connected to the output voltage, and
wherein the NMOS transistor has a body connected in common with the source and configured to receive the output voltage.

6. The buffer circuit of claim 5, wherein the source follower comprises:
a first source follower NMOS transistor having a gate connected to the input voltage, a drain connected to a power supply voltage, a source connected to the gate of the PMOS transistor of the second comparator, and a body connected in common with the source, and
wherein the source follower provides the corrected input voltage to the gate of the PMOS transistor of the second comparator.

7. The buffer circuit of claim 3, wherein the source current circuit comprises:
a first source PMOS transistor having a gate connected to the first comparator; a drain connected in common with the gate; and a source connected to a power supply voltage, and configured to allow a source reference current to flow therethrough; and
a second source PMOS transistor having a gate connected in common with the gate of the first source PMOS transistor; a drain connected to a fourth node of the load stage having a mirroring structure with and corresponding to a third node of the load stage connected to a gate terminal of the second output transistor; and a source connected to the power supply voltage, and configured to allow the source current to flow therethrough by mirroring the source reference current.

8. The buffer circuit of claim 3, wherein the sink current circuit comprises:
a first sink NMOS transistor having a gate connected to the second comparator; a drain connected in common with the gate; and a source connected to a ground voltage, and configured to allow a sink reference current to flow therethrough; and
a second sink NMOS transistor having a gate connected in common with the gate of the first sink NMOS transistor; a drain connected to a second node of the load stage having a mirroring structure with and corresponding to a first node of the load stage connected to a gate terminal of the first output transistor; and a source connected to the ground voltage, and configured to allow the sink current to flow therethrough by mirroring the sink reference current.

9. The buffer circuit of claim 1, wherein the load stage comprises:
a first differential mirror circuit having a current mirroring structure and a cascode structure, and configured to mirror the first and second differential currents and the sink current;
a second differential mirror circuit having a current mirroring structure and a cascode structure, and configured to mirror the third and fourth differential currents and the source current; and
a third bias circuit and a fourth bias circuit connected between the first differential mirror circuit and the second differential mirror circuit, and configured to control an operation in a static state and an amplification operation of the first differential mirror circuit and the second differential mirror circuit.

10. A buffer circuit configured to generate an output voltage according to an input voltage, comprising:
an input stage configured to provide first and second differential currents to a load stage or receive third and fourth differential currents from the load stage based on a difference between the input voltage and the output voltage;
a load stage configured to apply gate voltages to first and second output transistors of an output stage based on the first through fourth differential currents;
the output stage configured to regulate the output voltage based on the gate voltages applied to the first and the second output transistors; and
a slew rate compensator configured to regulate the gate voltages of the first and second output transistors by providing a source current to the load stage or receiving a sink current from the load stage,
wherein the slew rate compensator comprises:
a source follower configured to output a corrected input voltage obtained by reducing the input voltage by a threshold voltage of a MOS transistor; and
a second control circuit configured to control the corrected input voltage output from the source follower.

11. The buffer circuit of claim 10, wherein the second control circuit comprises:
a first control PMOS transistor configured to operate as a current source, and
a second control PMOS transistor having a drain connected to the first control PMOS transistor; a source connected to a power supply voltage; and a gate to which a gate voltage of the first output transistor is applied.

12. The buffer circuit of claim 10, wherein the slew rate compensator further comprises:
a first comparator configured to enter an ON operating state or an OFF operating state based on the difference between the input voltage and the output voltage;
a second comparator configured to enter an ON operating state or an OFF operating state based on a difference between the corrected input voltage and the output voltage;
a source current circuit configured to provide the source current to the load stage;
a sink current circuit configured to receive the sink current from the load stage;
a slew rate compensation switch configured to determine whether the source current circuit or the sink current circuit is operating; and
a first control circuit configured to control a magnitude of a current of the source follower,
wherein the source follower comprises a first source follower NMOS transistor having a gate connected to the input voltage; a drain connected to a power supply voltage; a source connected to a gate of a PMOS transistor of the second comparator; and a body connected in common with the source, and
wherein the source follower is configured to provide the corrected input voltage to the gate of the PMOS transistor of the second comparator.

13. The buffer circuit of claim 12, wherein the first control circuit comprises:
a first control NMOS transistor having a drain connected to the source follower; a source connected to a ground voltage; and a gate to which a gate voltage of the second output transistor is applied.

14. The buffer circuit of claim 12, wherein the first comparator comprises an NMOS transistor having a gate connected to the input voltage; a drain connected to the source current circuit; and a source connected to the output voltage,
wherein the second comparator comprises a PMOS transistor having a gate connected to the corrected input voltage output from the source follower; a drain connected to the sink current circuit; and a source connected to the output voltage, and
wherein the NMOS transistor has a body connected in common with the source and configured to receive the output voltage.

15. The buffer circuit of claim 12, wherein the source current circuit comprises:
a first source PMOS transistor having a gate connected to the first comparator; a drain connected in common with the gate; and a source connected to a power supply voltage, and configured to allow a source reference current to flow therethrough; and
a second source PMOS transistor having a gate connected in common with the gate of the first source PMOS transistor; a drain connected to a fourth node of the load stage having a mirroring structure with and corresponding to a third node of the load stage connected to a gate terminal of the second output transistor; and a source connected to the power supply voltage, and configured to allow the source current to flow therethrough by mirroring the source reference current.

16. The buffer circuit of claim 12, wherein the sink current circuit comprises:
a first sink NMOS transistor having a gate connected to the second comparator; a drain connected in common with the gate; and a source connected to a ground voltage, and configured to allow a sink reference current to flow therethrough; and
a second sink NMOS transistor having a gate connected in common with the gate of the first sink NMOS transistor; a drain connected to a second node of the load stage having a mirroring structure with and corresponding to a first node of the load stage connected to a gate terminal of the first output transistor; and a source connected to the ground voltage, and configured to allow the sink current to flow therethrough by mirroring the sink reference current.

17. The buffer circuit of claim 10, wherein the load stage comprises:
a first differential mirror circuit having a current mirroring structure and a cascode structure, and configured to mirror the first and second differential currents and the sink current;
a second differential mirror circuit having a current mirroring structure and a cascode structure, and configured to mirror the third and fourth differential currents and the source current; and
a third bias circuit and a fourth bias circuit connected between the first differential mirror circuit and the second differential mirror circuit, and configured to control an operation in a static state and an amplification operation of the first differential mirror circuit and the second differential mirror circuit.

18. A method for controlling a buffer circuit, the method comprising:
comparing an input voltage to an output voltage of the buffer circuit;
allowing a slew rate compensator to provide a source current to a load stage or receive a sink current from the load stage based on a difference between the input voltage and the output voltage;
allowing first and second compensation currents to flow through first and second differential mirror circuits of the load stage based on the source current and the sink current;
allowing gate voltages of first and second output transistors of an output stage to increase or decrease based on the first and second compensation currents; and
allowing the output voltage to follow a rising transition or a falling transition of the input voltage based on the increase or the decrease in the gate voltages of the first and second output transistors,
wherein the allowing of the output voltage to follow the rising transition or the falling transition of the input voltage further comprises:
allowing a first control circuit to be turned on or turned off.

19. The method of claim 18, further comprising:
when the input voltage is in a rising transition,
comparing the input voltage to the output voltage, wherein when the input voltage exceeds a value obtained by adding a threshold voltage of a MOS transistor to the output voltage, allowing the slew rate compensator to provide the source current to the load stage;
allowing the second compensation current to flow through the second differential mirror circuit based on the source current;
allowing the gate voltages of the first and second output transistors of the output stage to decrease based on the second compensation current;
allowing the output voltage to increase in response to the decrease in the gate voltages of the first and second output transistors and to follow the rising transition of the input voltage; and
allowing the first control circuit to be turned off and the second control circuit to be turned on according to the rising transition of the input voltage.

20. The method of claim 18, further comprising:
when the input voltage is in a falling transition,
providing the input voltage to a source follower and outputting a corrected input voltage obtained by reducing the input voltage by a threshold voltage of a transistor inside the source follower;
comparing the corrected input voltage to the output voltage, wherein when the corrected input voltage is less than a value obtained by subtracting a threshold voltage of a MOS transistor from the output voltage, allowing the slew rate compensator to receive the sink current from the load stage;
allowing the first compensation current to flow through the first differential mirror circuit based on the sink current;
allowing the gate voltages of the first and second output transistors of the output stage to increase based on the first compensation current;
allowing the output voltage to decrease in response to the increase in the gate voltages of the first and second output transistors and to follow the falling transition of the input voltage; and
allowing the first control circuit to be turned on and the second control circuit connected to the source follower to be turned off according to the falling transition of the input voltage.
